(19) United States
(12) Patent Application Publication
(10) Pub. No.: US 2026/0075771 A1
(43) Pub. Date: Mar. 12, 2026

(54) System and Method for Thermal Management for Circuit Breaker Panel

(71) Applicant: Koolbridge Energy, Inc., Wrightsville Beach, NC (US)

(72) Inventors: David Sturdy, Wilmington, NC (US); Robert Peterson, Wilmington, NC (US)

(21) Appl. No.: 19/319,344

(22) Filed: Sep. 4, 2025

Related U.S. Application Data
(60) Provisional application No. 63/691,836, filed on Sep. 6, 2024.

(51) Int. Cl. H05K 7/20

(52) U.S. Cl. CPC H05K 7/205; H05K 7/20454; H05K 7/20472

(57) ABSTRACT

Heat is passively removed from circuit breaker stabs in a circuit breaker panel (i.e., without the use of active components such as cooling fans), and transferred to the panel chassis for radiant dissipation. A thermally conductive, electrically insulating (TCEI) material is interposed between the breaker stabs and the chassis. The TCEI material both spreads heat from each breaker stab over a large area, and passively conducts the heat to the panel chassis. In some embodiments, heat spreaders attached to the breaker stabs and embedded in the TCEI material, and/or a main heat sink interposed between the TCEI material and the circuit breaker panel chassis, enhance the passive conductance of heat from the breakers to the chassis for radiant cooling.

### CROSS REFERENCE TO RELATED APPLICATIONS

This application claims priority to U.S. Provisional Patent Application No. 63/691,836, filed Sep. 6, 2024, the disclosure of which is hereby incorporated herein by reference, in its entirety.

### FIELD OF INVENTION

The present invention relates generally to electrical power distribution, and in particular to a system and method of thermal management in a residential circuit breaker panel.

### BACKGROUND

Residential solar power installations have grown dramatically in recent years, and the trend is for further growth. Several factors combine to drive this growth, including the high price of utility-provided electrical power; unreliability of the utility electrical grid in the face of natural disasters, excessive demand, and sabotage; dramatic decrease in the cost of photovoltaic panels; innovations in the capacity, reliability, and cost of storage batteries driven by the move to electric vehicles; and environmental concerns in the face of global climate change.

Traditionally, residential solar power systems have been “grid-tied,” with DC power from photovoltaic panels converted to AC power in an inverter acting as a current source, which feeds power to the utility electrical grid. This power is either separately metered and paid for by the utility, or fed back through the primary connection, turning the main meter backwards and thus reducing the homeowner's total cost of electricity. In either case, when power is unavailable from the utility grid, the solar system must be disconnected for the safety of linemen (known as anti-islanding), and is generally unable to generate power to run lights and appliances in the home. Alternatively, “off the grid” systems employ inverters acting in “stand-alone” mode as constant voltage sources, but these typically are able to supply only small amounts of power, and without extensive (and expensive) banks of storage batteries, power availability is limited to daytime and even then is at the whim of the weather.

U.S. Pat. No. 9,735,703, incorporated herein by reference in its entirety, describes a power distribution system for a residential solar power system that maximizes self-consumption of locally generated solar (or wind, etc.) power, while maintaining full access to utility grid power. Referred to as the SMART LOAD CENTER™ (SLC), a circuit breaker panel receives split-phase power from both the grid and an inverter operating in standalone mode (powered either directly by solar panels or from storage batteries), and distributes power to household loads by intelligently selecting between grid power and solar power on a circuit-by-circuit basis. The electrical code increasingly requires expensive ground fault circuit interrupter (GFCI) or arc fault circuit interrupter (AFCI) breakers. Accordingly, a feature of the SLC is that, for each load circuit, both grid and solar power (in the alternative) are routed through the same circuit breaker. Each load circuit additionally includes a current sensor to monitor the real-time energy consumption. A microprocessor manages the system, powering most or all loads from free solar power on sunny days; performing load shedding by switching certain load circuits to grid power at night and on cloudy days; and charging storage batteries. When the grid fails, the SLC isolates the home from the grid and powers load circuits from solar panels and/or batteries, according to user-defined priority and actual current consumption vs. capacity. In some embodiments, the system is also capable of grid-tied operation, selling excess power back to the utility grid (whether separately or commonly metered).

The SLC is innovative not only in its functionality, but also in its mechanical design. U.S. Pat. No. 10,951,027, incorporated herein by reference in its entirety, describes numerous innovations, including a central quad bus bar assembly routing two legs of split-phase power from two sources across the panel; and printed circuit boards (PCB), each containing two instances of a power selection relay connected to hot legs from two different power sources, a current sensor, and circuit breaker stab.

Residential power in the U.S. is 120 VAC split phase, meaning that each of two “hot” legs (L1, L2), taken from opposite ends of the secondary winding of a step-down transformer, are at 120 VAC with respect to a neutral line (N) taken from a center tap of the transformer (and grounded at the service entry point). The AC voltage waveforms on the hot legs are in anti-phase relationship. The hot legs have 240 VAC between them, which is distributed through two-pole circuit breakers to power high-demand loads such as an electric oven, water heater, well pump, electric tumble dryer, and the like. Residential circuits breakers are rated for a predetermined maximum current, ranging from 15 to 50 amps.

Like any real-world circuit, circuit breakers have a resistance, and hence generate heat when a current passes through them. Excessive heat build-up can deleteriously affect circuit breaker operation, leading to a fire hazard. Accordingly, industry specifications (e.g., UL) limit the allowable thermal rise of any circuit breaker. It is known in the art to remove heat from a circuit breaker panel by the use of exhaust fans. This increases both the initial and operating costs of the panel, and is a potential point of failure. If one or more fans fails, thermal rise on one or more circuit breakers could exceed the amount for which it was rated.

Thermal management stands as a major challenge in the design of advanced residential circuit breaker panels.

The Background section of this document is provided to place embodiments of the present invention in technological and operational context, to assist those of skill in the art in understanding their scope and utility. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

According to one or more embodiments described and claimed herein, heat is passively removed from circuit breaker stabs in a circuit breaker panel (i.e., without the use of active components such as cooling fans, Peltier effect plates, or the like), and transferred to the panel chassis for radiant dissipation. A thermally conductive, electrically insulating (TCEI) material is interposed between the breaker stabs and the chassis. The TCEI material both spreads heat from each breaker stab over a large area, and passively conducts the heat to the panel chassis. The TCEI material is in thermal contact with the back side of the breaker stabs—that is, the opposite side of the PCB from the side on which circuit breakers are installed. In some embodiments, heat spreaders attached to the breaker stabs and embedded in the TCEI material, and/or a main heat sink interposed between the TCEI material and the circuit breaker panel chassis, enhance the passive conductance of heat from the circuit breakers to the chassis for radiant cooling.

One embodiment relates to a circuit breaker panel. The panel includes a chassis, that is sized and configured to fit between studs in wood frame construction walls. The chassis includes at least two side walls and a top, bottom, and back wall collectively defining an interior. The panel further includes a printed circuit board (PCB) comprising a plurality of breaker stabs through-mounted on the PCB, the breaker stabs protruding on a first side of the PCB and positioned and configured to receive residential circuit breakers. The PCB is disposed within the interior of the panel. The panel further includes a thermally conductive, electrically insulating (TCEI) material interposed between a second side of the PCB opposite the first side, and the back wall of the chassis. The TCEI material is configured to conduct heat from the breaker stabs to the chassis for radiant cooling.

Another embodiment relates to a method of managing the generation of heat in a circuit breaker panel comprising a chassis sized and configured to fit between studs in wood frame construction walls. The chassis includes at least two side walls and a top, bottom, and back wall collectively defining an interior. A printed circuit board (PCB), comprising a plurality of breaker stabs through-mounted on the PCB, is provided. The breaker stabs protrude on a first side of the PCB and are positioned and configured to receive residential circuit breakers, The PCB is disposed within the interior of the panel. Heat is conducted from the breaker stabs to the chassis for radiant cooling via a thermally conductive, electrically insulating (TCEI) material interposed between a second side of the PCB opposite the first side, and the back wall of the chassis.

### BRIEF DESCRIPTION OF THE DRAWINGS

The present invention will now be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. Like numbers refer to like elements throughout.

FIG. 1 is a perspective view of a circuit breaker panel.

FIG. 2 is a perspective view of a PCB board with a bus bar assembly, relays, and surface-mount circuitry mounted thereon.

FIG. 3 is a plan view of the PCB of FIG. 2 attached to a rib plate, with breaker stabs installed on the PCB.

FIG. 4 is a perspective view of the back side of the PCB and rib plate of FIG. 3, with heat spreaders installed on half of the breaker stabs.

FIG. 5 is a plan view of a main heat sink.

FIG. 6 is a section view showing the well that is filled with TCEI material.

FIG. 7 is a perspective view of the back wall of the chassis of the circuit breaker panel of FIG. 1.

FIG. 8 is a flow diagram of a method of managing the generation of heat in the circuit breaker panel of FIG. 1.

### DETAILED DESCRIPTION

For simplicity and illustrative purposes, the present invention is described by referring mainly to an exemplary embodiment thereof. In the following description, numerous specific details are set forth in order to provide a thorough understanding of the present invention. However, it will be readily apparent to one of ordinary skill in the art that the present invention may be practiced without limitation to these specific details. In this description, well known methods and structures have not been described in detail so as not to unnecessarily obscure the present invention.

UL (originally Underwriter's Laboratory) is a national, private testing laboratory. UL creates and promulgates technical specifications related to product safety, and certifies samples of products as meeting the applicable specifications. As a practical matter, UL certification is a de facto requirement to market and sell electrical products in the U.S. One such certification, UL-67, relates to thermal rise of circuit breakers during use. In one testing scenario, a breaker in an enclosure passing 80% of its rated current may not exceed a 65° C. rise over ambient temperature, where the ambient value cannot exceed 40° C. for conducting the test.

In conventional circuit breaker panels, all breaker stabs on a given hot leg (L1, L2) are physically connected to the same metal bus bar, which provides a thermal path for distributing and evening out the heat generated by any one or more breakers. In a dual-source circuit breaker panel, circuit breakers are necessarily isolated from the hot leg distribution bus bars by a source selection function (e.g., one or more relays), and also optionally by current sensors and possibly other circuits. Hence, each individual circuit breaker must dissipate all the heat it generates, and remain within the UL-67 specification. In such situations, a 20 A breaker can pass this test. However, larger breakers, such as 50 A or 60 A typically cannot, without active cooling such as exhaust fans, Peltier effect coolers, or the like. More generally, electrical components exhibit shorter lifetimes and have more failures in high heat environments, so efficient passive cooling may be beneficial even for conventional, single-source circuit breaker panels.

According to embodiments of the present invention, a circuit breaker panel is configured such that heat is passively conducted from circuit breakers in the panel to the panel chassis, which acts as a passive, radiant heat sink for cooling the breakers.

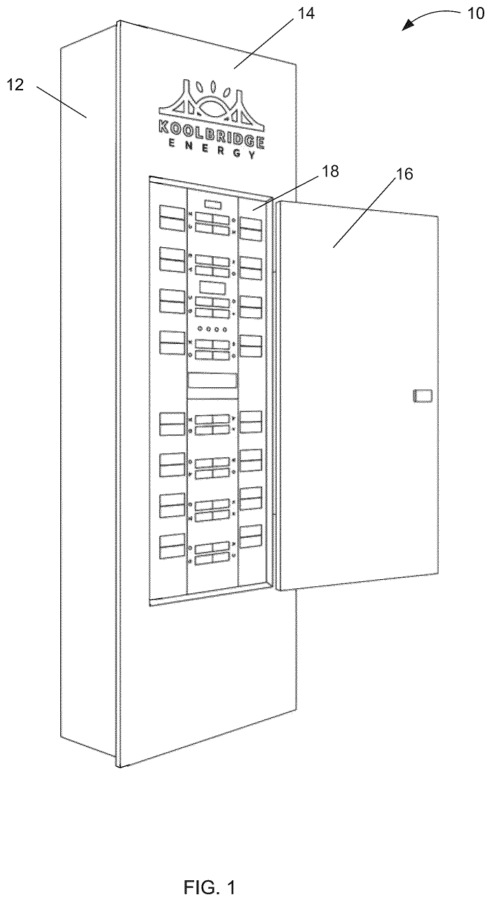

FIG. 1 shows a circuit breaker panel 10 according to embodiments of the present invention. The circuit breaker panel 10 comprises a chassis 12 that is sized and configured to fit between studs in wood frame construction walls. A front panel 14 extends in all four directions beyond the chassis 12; when installed, the front panel 14 is flush with, and on the exterior of, the wall covering, such as drywall. Like conventional circuit breaker panels, the chassis 12 has two side walls and a top, bottom, and back wall which collectively define an interior space. A door 16 covers the user access panel 18, which exposes the operating mechanism of each circuit breaker, and includes various lights and other displays that indicate, e.g., the power source currently supplying each load, operating status, and the like.

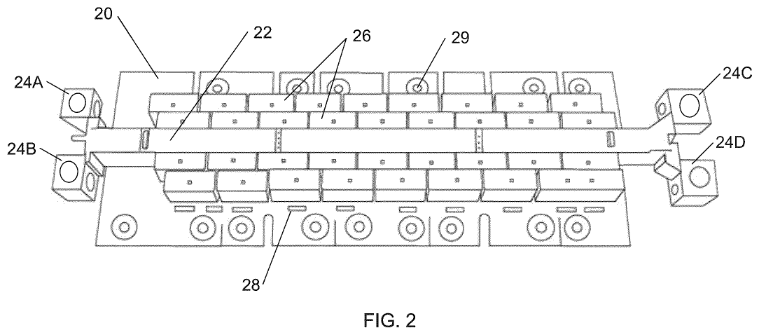

FIG. 2 shows a PCB 20 that is mounted within the interior of the chassis, such as by being secured to a dielectric attachment member (e.g., plastic or the like), referred to herein as a rib plate. Mounted on the front side if the PCB 20 is a central bus bar assembly 22. The bus bar assembly 22 in this embodiment comprises four electrically conductive bus bars, spaced apart from each other and encapsulated in a dielectric material, such as plastic or epoxy. Each bus bar connects to a power lug 24A-D. The lugs 24 are the connection points for the live lines L1, L2 of two different split-phase AC electrical power sources, such as a utility power grid and a secondary power source (e.g., generator, solar, wind, etc.). Protrusions (not shown) on the back of the bus bar assembly 22 connect each bus bar to mount points on the PCB. In other embodiments, such as where the circuit breaker panel 10 connects only to utility grid power, the bus bar assembly may include only two bus bars.

On each side of the bus bar assembly 22, two rows of relays 26 are mounted to the PCB 20. The relays select, for each branch circuit (i.e., each circuit breaker), one of the two power sources. In this embodiment, two relays 26 are used for each power source selection circuit, to provide break-before-make isolation between the bus bars when switching between power sources. Circuitry 28, such as current sensors, is surface-mounted on the PCB 20, and may be mounted on the opposite side of the PCB 20 as well (not shown). Through-holes 29 are provided for the installation of breaker stabs. The through-holes 29 are grouped in pairs, allowing for double-pole breakers, such as for 220V appliances or load circuits.

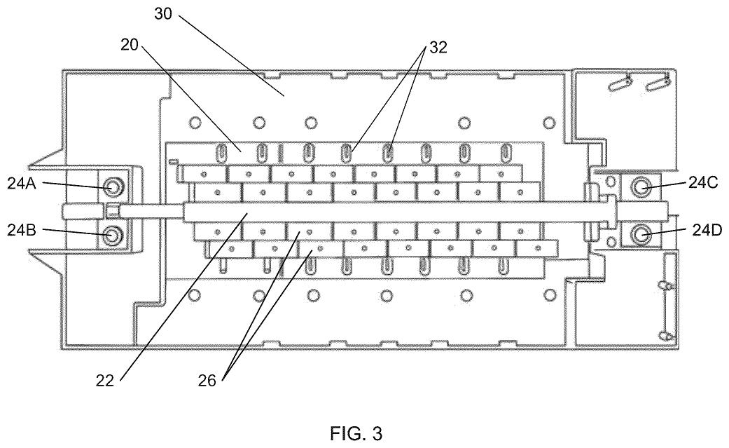

FIG. 3 shows the PCB 20, with all the circuitry attached, mounted to a dielectric rib plate 30. Breakers stabs 32 are installed in the through-holes 29.

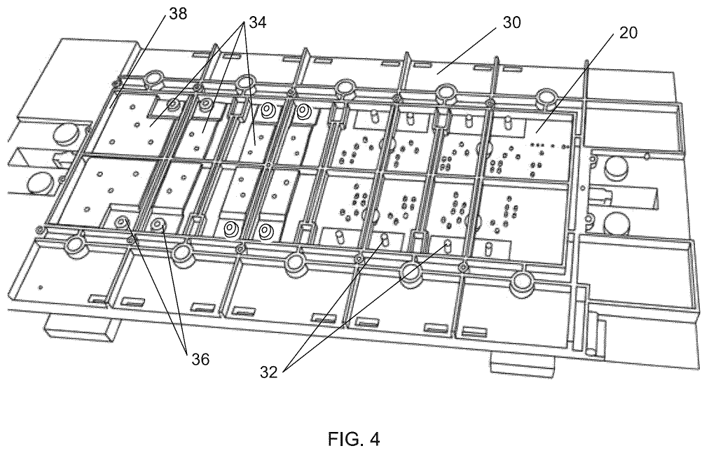

FIG. 4 is a view of the back side of the PCB 20 and rib plate 30, heat spreaders 34 attached to half of the breaker stabs 32 (the other half are shown prior to installation of the heat spreaders 34, to show the PCB 20. The back sides of the breaker stabs 32, protruding through the through-holes 29, are threaded. The heat spreaders 34 are affixed to the threaded breaker stabs 32 by nuts 36. The heat spreaders 34 are formed from a thermally conductive material such as copper, aluminum, silicon carbide, or the like. The heat spreaders 34 conduct heat away from the circuit breakers, through the breaker stabs 32. The heat spreaders 34 are preferably spaced apart from, and parallel with, the back side of the PCB 20 (other than at the point of attachment to the back side of respective breaker stabs 32), so that there is no contact with any electrical trace, surface mount component, protruding component pin, or the like. The heat spreaders 34 are preferably as large as practical, in the dimensions parallel to the plane of the PCB 20.

Note that the rib plate 30 forms short walls 38 around the periphery of the PCB 20, perpendicular to the plane of the PCB 20. These walls 38 and the PCB 20 define a thin rectangular well that is enclosed by the PCB 20 on the bottom and by the four walls 38 on the sides, with the top open.

A TCEI material is applied within this well, where it will be positioned between the back side of the PCB 20 and the back wall of the chassis 12 when the PCB 20 and rib plate 30 are installed in the chassis 12. The TCEI material is configured to conduct heat from the breaker stabs 32 and the heat spreaders 34 to the chassis 12 for radiant cooling, but not conduct any electricity. As one non-limiting example of a TCEI material, SYLGUARD™, available from Dow Corning, has a thermal conductivity of 0.62 W/m °K and a dielectric strength of 475 V/mil. SYLGUARD is a two-part encapsulant that, when mixed, is a fluid that hardens to a gel or solid form. In one embodiment, a gasket or the like may seal the space between the PCB 20 and the rib plate 30. Also, PCB 20 lacks through-vias in this area, such that the well can contain the TCEI material in its fluid state. The TCEI material is poured into the well in the fluid state. The TCEI material thus flows under and around the heat spreaders 34, preferably contacting both the PCB 20 and the heat spreaders 34. The TCEI material then hardens into a gel or solid form. The TCEI material is thus in physical and thermal contact with the back side of the PCB 20, the back sides of the breaker stabs 32, and the heat spreaders 34. The TCEI material both spreads the heat from individual breaker stabs 32, and transfers the heat towards the back wall of the panel chassis 12.

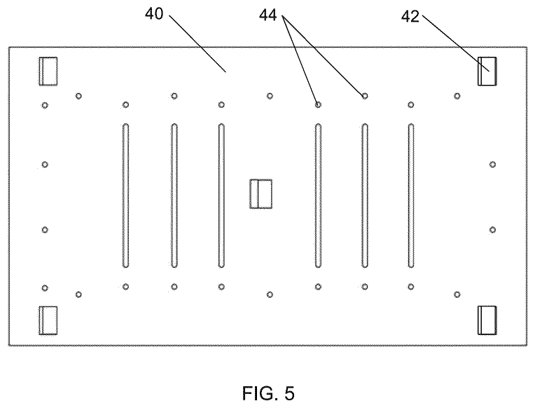

FIG. 5 shows a main heat sink 40, which is affixed to the back side of the rib plate 30 after application of the TCEI material. The main heat sink 40 further enhances the removal of heat from breaker stabs 32. The heat sink 40 is preferably formed of a thermally conductive metal, such as copper, aluminum, silicon carbide, or the like. The main heat sink 40 preferably covers most or all of the surface area of the TCEI material. The main heat sink 40 preferably contacts both the TCEI material and the back wall of the chassis 12, and is in thermal conduction relationship to both.

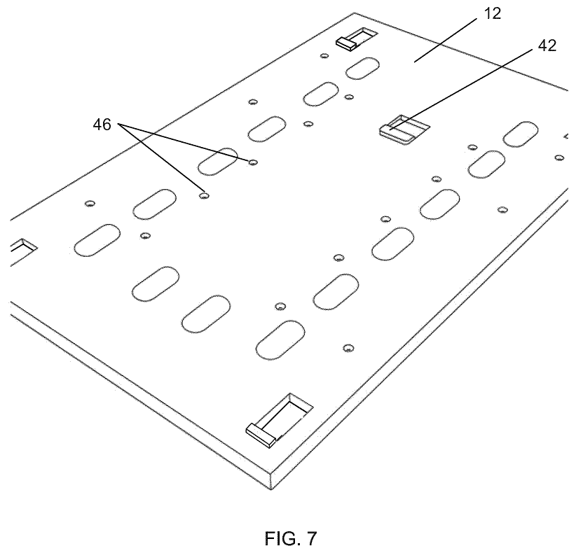

In one embodiment, an assembly is formed comprising the PCB 20 holding the circuit breakers; the rib plate 30 holding the PCB 20; TCEI material; heat spreaders 34 embedded in the TCEI material; and the main heat sink 40. This assembly may have aligned through-holes 44, which align with threaded holes 46 in the back wall of the panel chassis (see FIG. 7). For example, the through-holes 44 may be pre-formed in the rib plate 30 and main heat sink 40, and may be positioned so as to avoid the heat spreaders 34. Through-holes are then drilled through the hardened TCEI material, using the pre-formed holes 44 as a guide. As this assembly is affixed to the chassis 12 with fasteners running through these through-holes 44 and into threaded holes 46 in the back wall of the chassis 12, the main heat sink 40—sandwiched between the TCEI material and the back of the chassis 12—is drawn into contact with both, preferably over most or all of its surface area.

“Dog ear” hooks 42 formed on one side of the main heat sink 40 engage with slots formed in the back wall of the panel chassis 12, so that the assembly “hangs” in a predetermined position on the back wall, in which position the through-holes 44 align with the threaded holes 46. This greatly eases proper assembly in the field, ensuring that all fasteners engage the chassis 12, and spreading the engagement force evenly over the main heat sink 40.

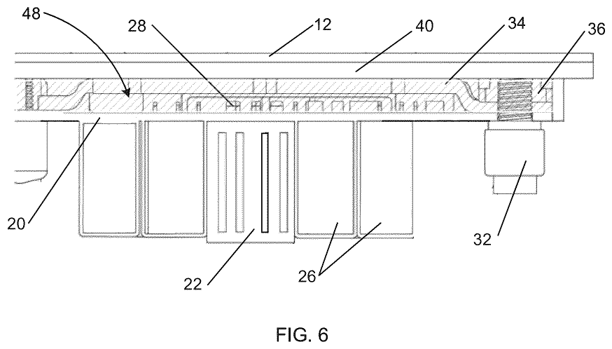

FIG. 6 is a section view showing the PCB 20, with the bus bar assembly 22, relays 26, and surface-mount circuitry 28 (such as current sensors) mounted on the PCB 20. Breaker stabs 32 are installed in through-holes 29 in the PCB 20, and a heat spreader 34 is attached to the back side of each breaker stab 32. The hatched area, indicated generally at 48, is filled with TCEI material. The main heat sink 40 contacts the TCEI material on one side, and the rear wall of the panel chassis 12 on the other side. A thermally conductive path thus exists from the breaker stabs 32, through the heat spreaders 34, TCEI material, and main heat sink 40, to the panel chassis 12. Note that at each step in this thermal path, the surface area encountered by heat traversing the path increases. Spreading the heat over successively larger surface areas reduces the overall thermal rise, and enhances radiant cooling. According to embodiments of the present disclosure, both a 125 amp and a 200 amp panel 10 pass UL-67 thermal testing, without any active cooling means.

FIG. 7 shows the back side of the circuit breaker panel chassis 12, with the hooks 42 of the main heat sink 40 engaging slots in the back wall of the chassis 12. After the PCB/TCEI/heat sink assembly is “hung” by hooks 42, fasteners attach the assembly to the threaded holes 46 in the back wall of the chassis 12.

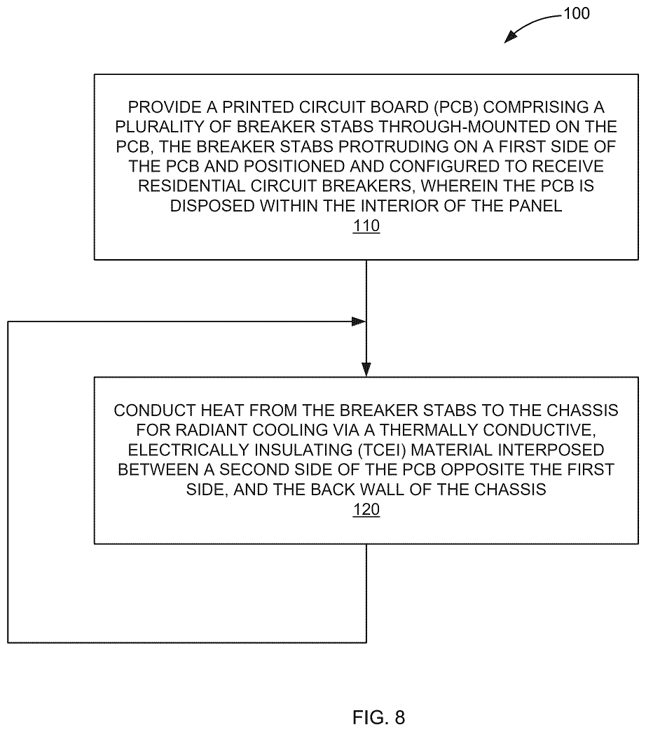

FIG. 8 shows the steps in a method 100 of managing the generation of heat in a circuit breaker panel 10. The panel 10 comprises a chassis 12 sized and configured to fit between studs in wood frame construction walls. The chassis 12 includes at least two side walls and a top, bottom, and back wall collectively defining an interior. a printed circuit board (PCB) 20 is provided (block 110). The PCB 20 comprises a plurality of breaker stabs 32 through-mounted on the PCB 20. The breaker stabs 32 protrude on a first side of the PCB 20, where they are positioned and configured to receive residential circuit breakers. The PCB 20 is disposed within the interior of the panel 10. Heat is conducted from the breaker stabs 32 to the chassis 12 for radiant cooling via a thermally conductive, electrically insulating (TCEI) material. The TCEI material is interposed between a second side of the PCB 20 opposite the first side, and the back wall of the chassis 12 (block 120). As indicated by the looping directional arrow, the block 120 is executed continuously.

Note that both the heat spreaders 34, and the main heat sink 40, are optional. The circuit breaker panel 10 can be assembled with neither, with either one alone, or, in a presently preferred embodiment, with both together. The heat spreaders 34 enhance thermal transfer from individual breaker stabs 32 to the TCEI material, and “spread” the heat within the TCEI material. Similarly, the main heat sink 40 enhances thermal transfer from the TCEI material to the back wall of the panel chassis 12, as well as protects the TCEI material from damage that could cause electrical shorts. The dog ear hooks 42 of the main heat sink 40 additionally assist in installation of the panel 10 in the field, helping to ensure that it is installed properly, to achieve maximum efficiency in passively transferring heat from the breaker stabs 32 to the chassis 12 for radiant cooling.

Although embodiments of the present invention have been described herein with reference to a dual-source circuit breaker panel, in which each load circuit automatically selects between grid power and, e.g., solar power, the invention is not limited to this application. In general, any circuit breaker panel 10 in which circuit breakers conduct high current and generate high thermal rise, may benefit from the thermal management concepts described and claimed herein. Furthermore, those of skill in the art will readily recognize that the circuit breaker panel 10 described herein can be expanded to distribute power from three or more sources; to distribute DC power in addition to, or as an alternative to, AC power; and other variations.

Embodiments of the present invention present numerous advantages over the prior art, and provide the following technical effects. Prior art passive cooling schemes, such as putting heat sinks on the circuit breakers, may help transfer heat away from the breakers, but the heat is still trapped within the interior of the panel. By providing a passive thermal channel from each circuit breaker to the panel chassis 12, the chassis 12 effectively becomes a large heat sink for radiating heat away from the breakers, without trapping the heat. Prior art active cooling schemes, such as exhaust fans, Peltier effect coolers, and the like, themselves consume power. They may also generate noise, and are subject to failure. If an active cooler fails, heat may build up in the circuit breakers that exceeds the UL limit to which they were certified, creating a hazard.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

1. A circuit breaker panel, comprising:
a chassis sized and configured to fit between studs in wood frame construction walls, the chassis including at least two side walls and a top, bottom, and back wall collectively defining an interior;
a printed circuit board (PCB) comprising a plurality of breaker stabs through-mounted on the PCB, the breaker stabs protruding on a first side of the PCB and positioned and configured to receive residential circuit breakers, wherein the PCB is disposed within the interior of the panel; and
a thermally conductive, electrically insulating (TCEI) material interposed between a second side of the PCB opposite the first side, and the back wall of the chassis;
wherein the TCEI material is configured to conduct heat from the breaker stabs to the chassis for radiant cooling.

2. The circuit breaker panel of claim 1 further comprising:
a dielectric rib plate to which the PCB is attached, the rib plate having walls generally perpendicular to the plane of the attached PCB and defining a well with the second side of the PCB as a floor of the well; and
wherein the TCEI material is disposed in the well and in thermal contact with the breaker stabs on the second side of the PCB.

3. The circuit breaker panel of claim 2 wherein the TCEI material is initially a viscous liquid poured into the well, that hardens to a gel or solid.

4. The circuit breaker panel of claim 2 further comprising:
a heat spreader formed from a thermally conductive material and attached to a breaker stab on the second side of the PCB, wherein the heat spreader is in thermal conduction relationship with the TCEI material.

5. The circuit breaker panel of claim 4 wherein the heat spreader is at least partially encapsulated within the TCEI material.

6. The circuit breaker panel of claim 4 wherein the heat spreader is generally planar, and generally parallel to the PCB.

7. The circuit breaker panel of claim 6 wherein the heat spreader is spaced apart from, and electrically isolated from, the PCB other than at the point of attachment to the breaker stab.

8. The circuit breaker panel of claim 2 further comprising:
a main heat sink interposed between the TCEI material and the back wall of the chassis, and configured in thermal conduction relationship to the TCEI material and the back wall.

9. The circuit breaker panel of claim 8 wherein the main heat sink contacts substantially the entire surface of the TCEI material.

10. The circuit breaker panel of claim 8 wherein the PCB, rib plate, TCEI material, and main heat sink have aligned through-holes aligned with threaded holes in the back wall of the chassis, and wherein when fasteners secure the PCB, rib plate, TCEI material, and main heat sink to the back wall, the TCEI material is drawn into physical and thermal contact with both the second side of the PCB and the main heat sink, and the main heat sink is drawn into physical and thermal contact with the back wall of the chassis, establishing a thermal path from breaker stabs on the PCB to the chassis.

11. A method of managing the generation of heat in a circuit breaker panel comprising a chassis sized and configured to fit between studs in wood frame construction walls, the chassis including at least two side walls and a top, bottom, and back wall collectively defining an interior, comprising:
providing a printed circuit board (PCB) comprising a plurality of breaker stabs through-mounted on the PCB, the breaker stabs protruding on a first side of the PCB and positioned and configured to receive residential circuit breakers, wherein the PCB is disposed within the interior of the panel; and
conducting heat from the breaker stabs to the chassis for radiant cooling via a thermally conductive, electrically insulating (TCEI) material interposed between a second side of the PCB opposite the first side, and the back wall of the chassis.

12. The method of claim 11 further comprising:
attaching the PCB to a dielectric rib plate, the rib plate having walls generally perpendicular to the plane of the attached PCB and defining a well with the second side of the PCB as a floor of the well; and
disposing the TCEI material in the well and in thermal contact with the breaker stabs on the second side of the PCB.

13. The method of claim 12 wherein disposing the TCEI material in the well comprises pouring the TCEI material as a viscous liquid into the well, and subsequently allowing the TCEI material to harden to a gel or solid.

14. The method of claim 12 further comprising:
attaching a heat spreader formed from a thermally conductive material to a breaker stab on the second side of the PCB, wherein the heat spreader is in thermal conduction relationship with the TCEI material.

15. The method of claim 14 wherein the heat spreader is at least partially encapsulated within the TCEI material.

16. The method of claim 14 wherein the heat spreader is generally planar, and generally parallel to the PCB.

17. The method of claim 16 wherein the heat spreader is spaced apart from, and electrically isolated from, the PCB other than at the point of attachment to the breaker stab.

18. The method of claim 12 further comprising:
interposing a main heat sink between the TCEI material and the back wall of the chassis, wherein the main heat sink is in thermal conduction relationship to the TCEI material and the back wall.

19. The method of claim 18 wherein the main heat sink contacts substantially the entire surface of the TCEI material.

20. The method of claim 18 wherein the PCB, rib plate, TCEI material, and main heat sink have aligned through-holes aligned with threaded holes in the back wall of the chassis, and further comprising securing the PCB, rib plate, TCEI material, and main heat sink to the back wall with fasteners, whereby the TCEI material is drawn into physical and thermal contact with both the second side of the PCB and the main heat sink, and whereby the main heat sink is drawn into physical and thermal contact with the back wall of the chassis, establishing a thermal path from breaker stabs on the PCB to the chassis.
